(19) United States
(12) Patent Application Publication
(10) Pub. No.: US 2008/0299467 A1
(43) Pub. Date: Dec. 4, 2008

(54) Mask mold, manufacturing method thereof, and method for forming large-sized micro pattern using mask mold

(75) Inventors: Jeong Gil Kim, Suwon-si (KR); Young Tae Cho, Daeleon (KR); Young Suk Sim, Daejeon (KR); Sung Hoon Cho, Suwon-si (KR); Suk Won Lee, Yongin-si (KR); Seon Mi Park, Suwon-si (KR); Sin Kwon, Suwon-si (KR); Jung Woo Seo, Hwaseong-si (KR); Jung Woo Park, Suwon-si (KR); Sung Woo Cho, Seoul (KR)

Correspondence Address: STAAS & HALSEY LLP, SUITE 700, 1201 NEW YORK AVENUE, N.W., WASHINGTON, DC, 20005, US

(73) Assignee: SAMSUNG ELECTRONICS CO., LTD., Suwon-si (KR)

(21) Appl. No.: 12/149,520

(22) Filed: May 2, 2008

(30) Foreign Application Priority Data
May 31, 2007 (KR) 10-2007-0053228

(51) Int. Cl. G03F 1/14; B05D 3/06

(52) U.S. Cl. 430/5; 427/372.2

(57) ABSTRACT

Disclosed are a mask mold, a manufacturing method thereof, and a method for forming a large-sized micro pattern using the manufactured mask mold, in which the size of a nano-level micro pattern can be enlarged using a simple method with low cost and interference and stitching errors between cells forming a large area can be minimized. The method for manufacturing the mask mold includes the operations of coating resist on a mask or a plurality of small molds having an engraved micro pattern, pressing the small molds to imprint the micro pattern on the resist, curing the resist, and releasing the small molds from the resist.

### CROSS-REFERENCE TO RELATED APPLICATIONS

This application claims the benefit of Korean Patent Application No. 10-2007-0053228, filed on May 31, 2007, in the Korean Intellectual Property Office, the disclosure of which is incorporated herein by reference.

### BACKGROUND

1. Field

One or more embodiments relate to a mask mold, a manufacturing method thereof, and a method for forming a large-sized micro pattern using the manufactured mask mold. More particularly, the embodiments relate to a mask mold, a manufacturing method of the mask mold, and a method for forming a large-sized micro pattern using the manufactured mask mold, in which the size of a micro pattern engraved on a small mold can be enlarged using a plurality of mask molds which can be manufactured using a simple method.

2. Description of the Related Art

According to nano-imprint technology, a substrate coated with thermoplastic resin or photocurable resin is pressed by a mold having a micro pattern with a nano-size of 1 to 100 nm engraved through an e-beam lithography method and the like, and then is cured, so that the pattern is transferred to the substrate.

The nano-imprint technology can generate an ultra micro pattern through a relatively simple process as compared with the conventional photolithography technology, resulting in high productivity and low manufacturing cost. Accordingly, the nano-imprint technology has been highlighted as technology for forming circuits for the next generation semiconductor and flat display.

An e-beam lithography process generally used for manufacturing a mold having a nano-sized pattern mainly utilizes a 6 or 8-inch wafer. When the size of a micro pattern is enlarged using the wafer, the cost increases in geometrical progression or a large-sized micro pattern larger than a predetermined size cannot be manufactured due to limitation in equipments. Further, in a case in which a pattern to be transferred requires a three dimensional complicated process, the manufacturing time and cost increase in order to enlarge the size of the pattern at one time.

In order to solve the problems as described above, Korean Unexamined patent Publication No. 2005-0075580 discloses a method for enlarging the size of a micro pattern by means of a small mold having a micro pattern according to a step-and-repeat scheme. As illustrated in FIG. 1, according to the step-and-repeat scheme, resist 3 is coated on a large-sized substrate 1, and a small mold 2 having a micro pattern engraved through an e-beam lithography process is aligned at a first fixed position on the large-sized substrate 1 by using an alignment system 4. Then, the small mold 2 is pressed to locally imprint the micro pattern on the resist 3. After the first imprinting is performed, the resist 3 is cured and the small mold 2 is released from the resist 3. Then, the imprinting process is repeated while moving the alignment system 4, so that micro pattern is formed on the entire surface of the large-sized substrate 1.

However, as the size of a substrate becomes larger, the imprinting process time also increases. Further, alignment errors between cells (small areas in which patterns are formed during the imprinting process using the small mold) frequently occur due to the continuous repeating of the small mold.

According to the step-and-repeat scheme, when the resist is cured using a thermal method, only an area to be imprinted on the substrate must be locally heated. Further, when the resist is cured using ultraviolet rays, the dispensing amount of the resist and the z direction position of the mold must be precisely controlled in order to prevent adjacent cells from being subject to the repeated imprinting.

That is, in the case of enlarging the size of the micro pattern using the step-and-repeat scheme, when alignment errors between cells occur or the dispensing amount of the resist is not precisely controlled, interference and stitching errors (an area without patterns occurs or undesired patterns are formed) between cells may occur.

### SUMMARY

Additional aspects and/or advantages will be set forth in part in the description which follows and, in part, will be apparent from the description, or may be learned by practice of the invention.

Accordingly, it is an aspect of the embodiment to provide a mask mold, a manufacturing method of the mask mold, and a method for forming a large-sized micro pattern using the manufactured mask mold, in which the size of a nano-level micro pattern can be enlarged using a simple method with low cost and interference and stitching errors between cells forming a large area can be minimized.

Additional aspects and/or advantages of the embodiment will be set forth in part in the description which follows and, in part, will be apparent from the description, or may be learned by practice of the invention.

The foregoing and/or other aspects of the embodiment are achieved by providing a method for manufacturing a mask mold, which includes the steps of: coating resist on a mask or a plurality of small molds having an engraved micro pattern; pressing the small molds to imprint the micro pattern on the resist; curing the resist; and releasing the small molds from the resist.

The method includes cleaning residual uncured resist.

The mask has a structure in which a chrome (Cr) layer is coated on a glass substrate or a quartz substrate.

The mask includes patterns formed on bright and dark regions and the chrome (Cr) layer is coated on the dark region.

The mask includes an align mask. The resist uses UV curable polymer resin and is cured by ultraviolet rays. Further, only resist on the bright region of the mask is cured.

The micro pattern includes a nano-level grid pattern for a wire grid polarizer, and a nano-level or micro-level functional pattern having a concave-convex section such as a reflective pattern having a three dimensional shape.

The foregoing and/or other aspects of the embodiment are achieved by providing a method for forming a large-sized micro pattern using a mask mold, which includes: preparing a mask mold by forming micro patterns, which are engraved on a plurality of small molds, on one mask; and forming the micro patterns of the mask mold on a large-sized substrate.

The large-sized micro pattern is formed through the operations: coating resist on the large-sized substrate or the mask mold; aligning the large-sized substrate and the mask mold; pressing the mask mold to imprint the micro patterns on the resist; curing the resist; releasing the mask mold from the resist; and cleaning residual uncured resist.

The method further includes: forming the micro patterns on a whole area of the large-sized substrate by repeating the operations.

The resist uses UV curable polymer resin and is cured by ultraviolet rays.

Further, resist, which is used for manufacturing the mask mold, includes a material different from a material of the resist used for forming the large-sized micro pattern. When the two resists use same material, release coating is performed relative to the resist of the mask mold.

Further, in the operation of aligning the large-sized substrate and the mask mold, the large-sized substrate and the mask mold are aligned in such a manner that an align mark formed on the mask mold matches with an align mark formed on the large-sized substrate, and then are aligned in such a manner that a boundary of the micro patterns previously formed on the large-sized substrate matches with a boundary of micro patterns of the mask mold to be additionally formed.

In the operation of curing the resist, only resist between a bright region of the mask mold and the large-sized substrate is cured.

The foregoing and/or other aspects of the embodiment are achieved by providing a mask mold comprising: a mask: and resist locally forming a micro pattern on the mask.

The mask includes patterns formed on bright and dark regions. The micro pattern is formed on only the bright region of the mask.

The micro pattern includes a nano-level grid pattern for a wire grid polarizer, and a nano-level or micro-level functional pattern having a concave-convex section such as a reflective pattern having a three dimensional shape.

### BRIEF DESCRIPTION OF THE DRAWINGS

These and/or other aspects and advantages of the embodiment will become apparent and more readily appreciated from the following description of the embodiments, taken in conjunction with the accompanying drawings of which:

FIG. 1 is a sectional view schematically showing a conventional nano imprinting process using a step-and-repeat scheme.

FIGS. 2A to 2H are sectional views illustrating the procedure for manufacturing mask molds and forming a large-sized micro pattern using the manufactured mask molds according to embodiment;

FIG. 3 is a view illustrating arrangement of mask molds for forming the large-sized micro pattern and a repeated imprinting process according to another embodiment; and

FIG. 4 is a flow diagram illustrating a method for forming a large-sized micro pattern according to an embodiment.

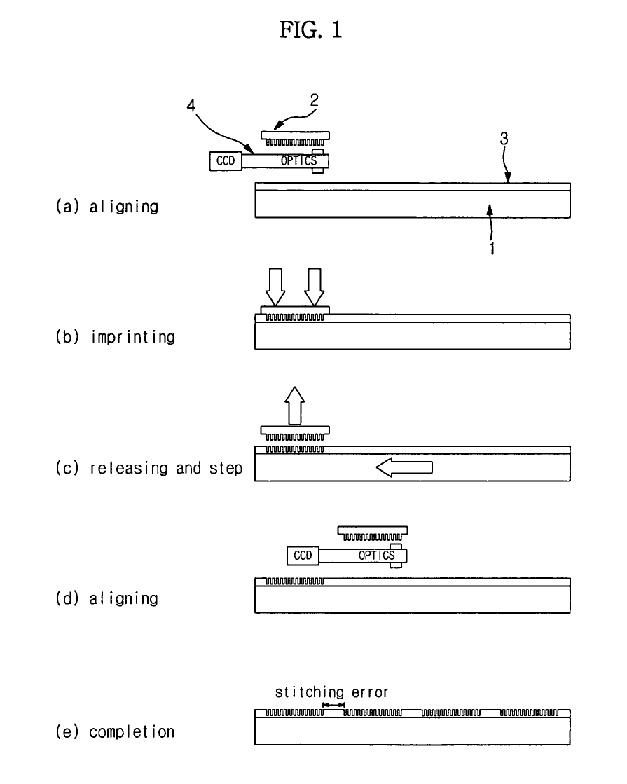

### DETAILED DESCRIPTION OF THE EMBODIMENTS

Reference will now be made in detail to the embodiment, an example of which is illustrated in the accompanying drawings, wherein like reference numerals refer to the like elements throughout. The embodiment is described below to explain the present invention by referring to the figures.

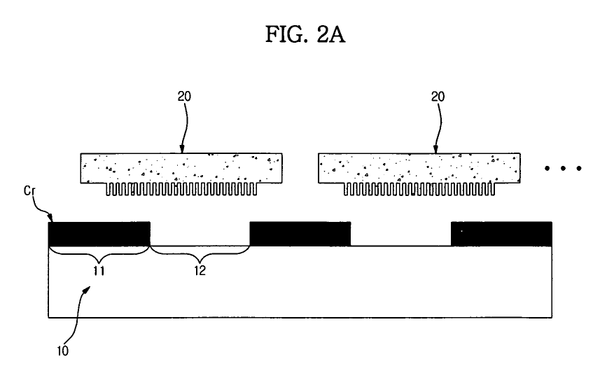

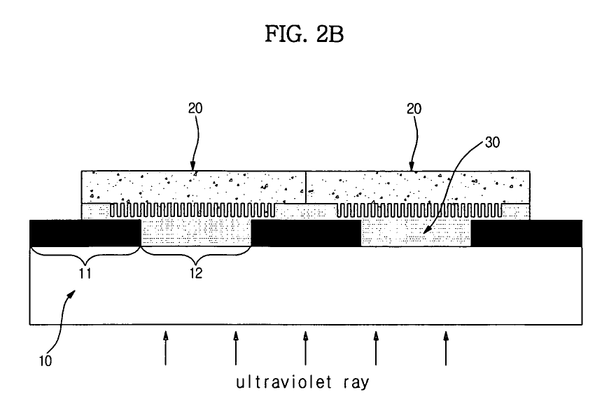

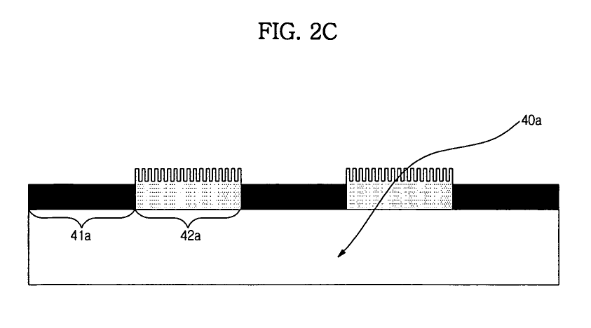

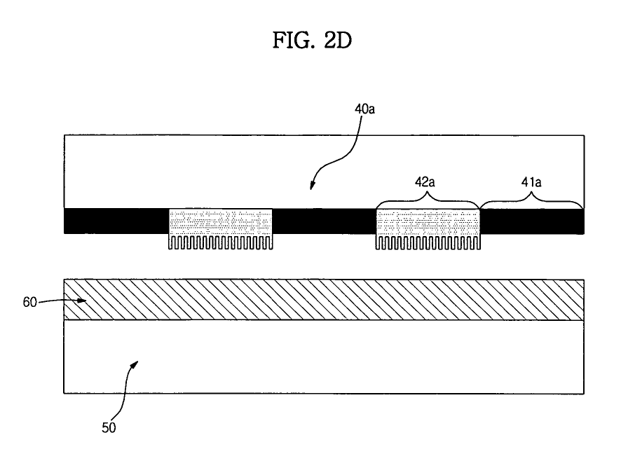

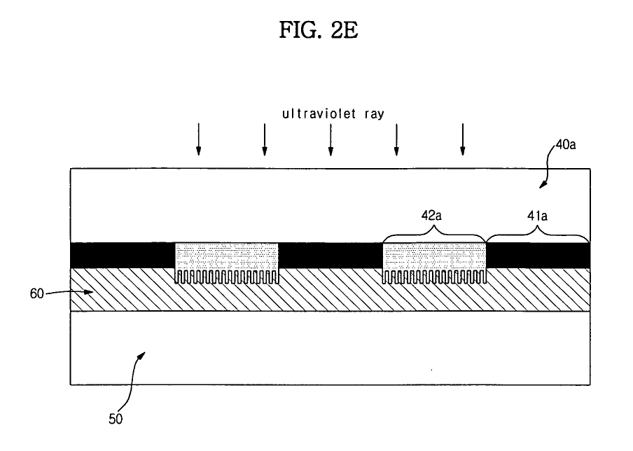

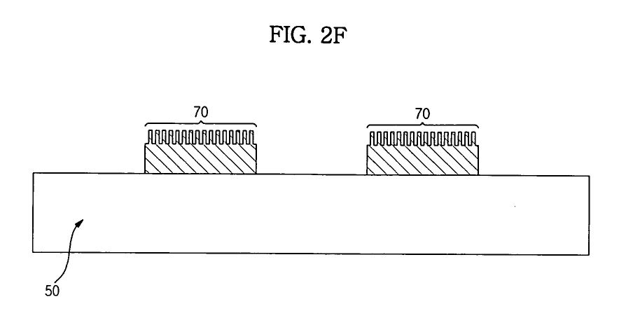

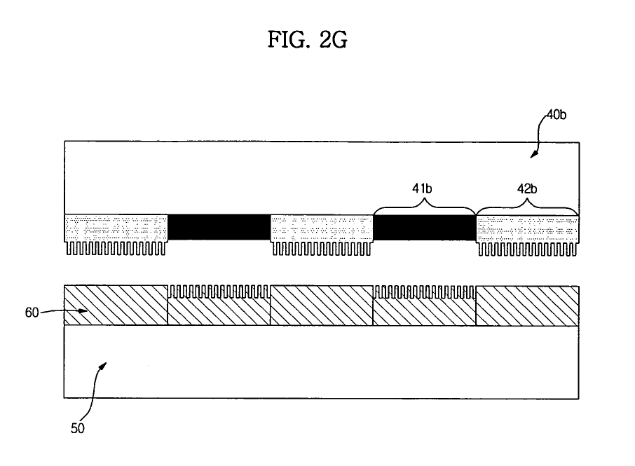

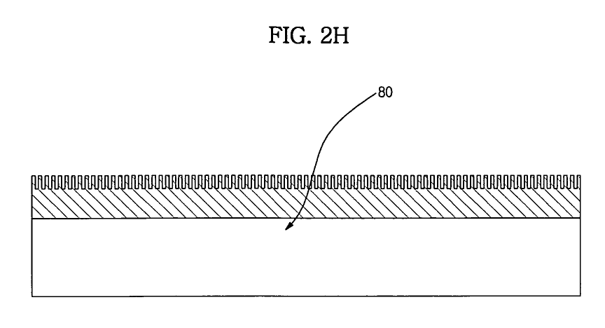

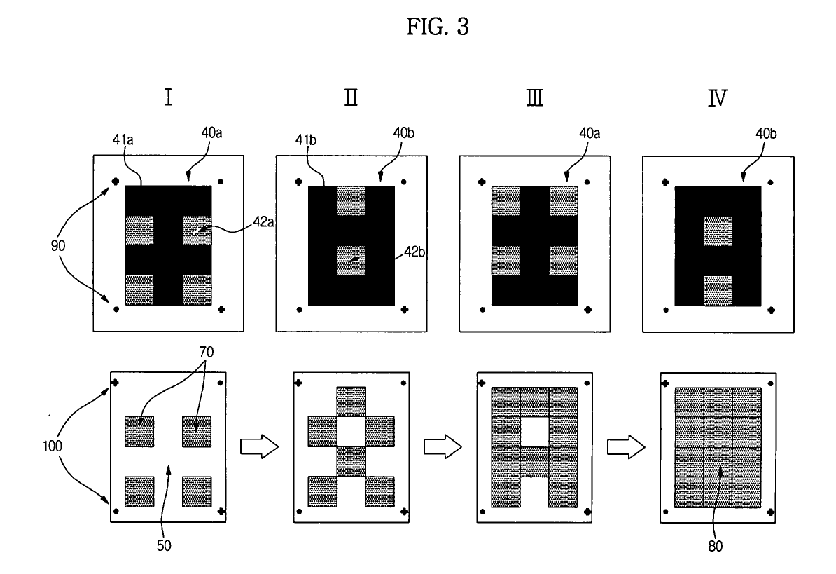

FIGS. 2A to 2H are sectional views illustrating the procedure for manufacturing mask molds and forming a large-sized micro pattern using the manufactured mask molds according to an embodiment. FIG. 3 is a view illustrating arrangement of the mask molds for forming the large-sized micro pattern and a repeated imprinting process according to an embodiment.

Hereinafter, an embodiment will be described in detail with reference to FIGS. 2A to 2H and FIG. 3.

FIGS. 2A to 2C shows the method for manufacturing the mask molds 40a and 40b of FIG. 2G. In order to manufacture the mask molds 40a and 40b, a plurality of small molds 20 having micro patterns engraved through the e-beam lithography method are prepared. The small molds 20 may have the same pattern or may also have different patterns. The micro pattern may include a nano-level grid pattern for a wire grid polarizer used for manufacturing a polarizing plate or an LCD substrate, a nano-level or micro-level functional pattern having a concave-convex section such as a reflective pattern having a three dimensional shape, etc.

Then, a mask 10 used in a photolithography process is manufactured. The mask 10 has a substrate structure in which one surface of the mask 10 is formed with a predetermined pattern using an emulsion or a metal layer. The mask 10 is manufactured by coating an opaque layer on a glass substrate or a quartz substrate that allows ultraviolet rays to pass therethrough, coating a photoresist layer on the opaque layer, and then patterning the photoresist layer by using e-beam, laser and the like. According to an embodiment, chrome (Cr) is used as a material for the opaque layer, and an align mark or an align key is provided in the mask. In addition, patterns are formed on bright and dark regions of the mask (see FIG. 2A and the upper figures of FIG. 3).

As illustrated in FIG. 2B, resist 30 is coated on the mask 10 or the small molds 20. The resist may use UV curable polymer resin.

Next, the small molds 20 having engraved micro patterns are pressed using (not shown) and the like, so that the micro patterns are imprinted on the resist 30. Ultraviolet rays are irradiated onto the resist 30 from the bottom of the mask 10 to cure the resist 30. In detail, the ultraviolet rays do not pass through the dark regions 11 of the mask 10, on which the Cr layer is coated, but pass through the bright regions 12 of the mask 10, on which the Cr layer is not coated, so that only the resist 30 coated on the bright regions 12 is cured by the ultraviolet rays.

Thereafter, the small molds 20 are released from the resist 30, and residual uncured resists on the dark regions 11 are cleaned using alcohol and the like, so that the mask mold 40a is completed (see FIG. 2C). The mask molds 40a and 40b are manufactured corresponding to the number of pattern types of the mask 10. In the present embodiment, two types of mask molds 40a and 40b are manufactured using two types of masks as illustrated in FIG. 3.

Hereinafter, the method for forming the large-sized micro pattern using the completed mask molds 40a and 40b will be described in detail with reference to FIGS. 2A to 2H.

As illustrated in FIG. 2D, resist 60 is coated on a large-sized substrate 50 or the mask mold 40a. The resist 60 utilizes the UV curable polymer resin used for manufacturing the mask molds 40a and 40b. The resist 30, which is used for manufacturing the mask mold in order to prevent adhesive phenomenon between resists, uses a material different from that of the resist 60 used for forming the large-sized micro pattern. When the resist 30 and the resist 60 use the same material, release coating may be performed on the resists of the mask molds 40a and 40b.

Then, the large-sized substrate 50 and the mask mold 40a are aligned, and the mask mold 40a is pressed using a roller and the like to imprint the micro pattern on the resist 60. The large-sized substrate 50 and the mask mold 40a are aligned in such manner that the align mark 100 of the large-sized substrate can match with the align mark 90 of the mask (mold). Next, as illustrated in FIG. 2E, ultraviolet rays are irradiated onto the resist 60 from the top of the mask mold 40a to cure the resist 60. In detail, the ultraviolet rays do not pass through the dark regions 41a of the mask mold 40a, but pass through the bright regions 42a of the mask mold 40a, so that only the resist between the bright regions 42a and the large-sized substrate 50 is cured by the ultraviolet rays.

Thereafter, the mask mold 40a is released from the resist 60, and residual uncured resists between the non-cured dark regions 41a and the large-sized substrate 50 are cleaned using alcohol and the like, so that the micro pattern is formed on the large-sized substrate 50 (see FIG. 2F).

The first imprinting process is performed using the mask mold 40a, so that the micro pattern is formed on the large-sized substrate 50 as illustrated in the lower leftmost figure of FIG. 3.

As illustrated in FIG. 2G, the processes of resist coating [symbol] aligning [symbol] imprinting [symbol] curing [symbol] releasing [symbol] cleaning are performed using the other type of mask mold 40b, thereby obtaining the large-sized substrate 50 on which the micro pattern is formed as illustrated in the lower second figure of FIG. 3.

Then, the large-sized substrate 50 and the mask mold 40b are aligned in such a manner that the boundary of the micro pattern previously formed on the large-sized substrate 50 can match with the boundary of a micro pattern of the mask mold 40b, which is to be additionally formed (generally, within the align error of ±1.5 μm).

Next, as illustrated in the upper figures of FIG. 3, the third and fourth imprinting processes are performed after rotating the mask molds 40a and 40b at the angle of 180°, respectively. As a result, as illustrated in the lower figures of FIG. 3, the micro pattern is gradually increased on the large-sized substrate 50. Finally, a product 80 having a large-sized micro pattern on the whole area of the large-sized substrate 50 can be obtained.

That is, the processes of FIGS. 2D to 2F are repeated using the two types of mask molds 40a and 40b, so that the large-sized micro pattern product 80 without interference and stitching errors between cells 70 can be completed as illustrated in FIG. 2H.

According to embodiments as described above, the interference and stitching errors between cells 70 forming a large area can be minimized through the alignment of the large-sized substrate 50 and the mask molds 40a and 40b, and the curing of the resists (only the resists between the bright regions 42a and 42b of the mask mold and the large-sized substrate 50 are cured by ultraviolet rays) are performed.

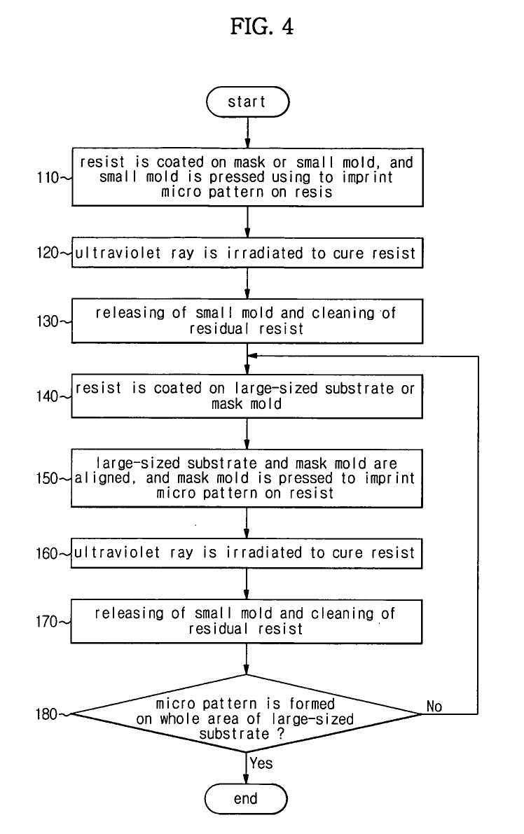

Hereinafter, the method for forming the large-sized micro pattern according to another embodiment will be described with reference to FIG. 4.

First, the small molds 20 having engraved micro patterns are prepared and the mask 10 having patterns formed on the bright region 12 and the dark region 11 is manufactured.

Then, the resist 30 is coated on the mask 10 or the small molds 20, and the small molds 20 are pressed using a roller and the like to imprint the micro patterns on the resist 30 (110).

Next, ultraviolet rays are irradiated onto the resist 30 from the bottom of the mask 10 to cure the resist 30 (120). Only the resist coated on the bright region 12 of the mask is cured.

The small molds 20 are released from the resist 30 and residual uncured resists are cleaned using alcohol and the like, so that the mask molds 40a and 40b are completed (130).

The resist 60 is coated on the large-sized substrate 50 or the mask molds 40a and 40b in order to enlarge the size of the micro pattern by using the mask molds 40a and 40b manufactured in operations 110, 120 and 130 (140).

The large-sized substrate 50 and the mask molds 40a and 40b are aligned, and the mask molds 40a and 40b are pressed using a roller and the like to imprint the micro pattern on the resist 60 (150).

Ultraviolet rays are irradiated onto the resist 60 from the top of the mask molds 40a and 40b to cure the resist 60 (160). Only the resists between the bright regions 42a and 42b of the mask molds and the large-sized substrate 50 are cured.

The mask molds 40a and 40b are released from the resist 60 and residual uncured resists are cleaned using alcohol and the like (170).

Then, whether or not the micro pattern is formed on the whole area of the large-sized substrate 50 is determined (180). When the micro pattern is not formed on the whole area of the large-sized substrate 50, the procedure returns to operation 140 and then operations 140, 150, 160 and 170 are repeated until the micro pattern is formed on the whole area of the large-sized substrate 50. However, when the micro pattern is formed on the whole area of the large-sized substrate 50, the imprinting process ends.

According to the embodiments as described above, the size of the nano-level pattern or the micro pattern having a three dimensional complicated shape can be enlarged using a simple method with low cost.

Further, according to the embodiments, the interference and stitching errors between cells forming a large area can be minimized.

Although few embodiments have been shown and described, it would be appreciated by those skilled in the art that changes may be made in these embodiments without departing from the principles and spirit of the invention, the scope of which is defined in the claims and their equivalents.

1. A method for manufacturing a mask mold, the method comprising:
coating resist on a mask or on a plurality of small molds having an engraved micro pattern;
pressing the small molds to imprint the micro pattern on the resist;
curing the resist; and
releasing the small molds from the resist.

2. The method as claimed in claim 1, further comprising cleaning residual uncured resist.

3. The method as claimed in claim 1, wherein the mask has a structure in which a chrome (Cr) layer is coated on a glass substrate or a quartz substrate.

4. The method as claimed in claim 3, wherein the mask includes patterns formed on bright and dark regions and the chrome (Cr) layer is coated on the dark region.

5. The method as claimed in claim 1, wherein the mask includes an align mask.

6. The method as claimed in claim 1, wherein the resist uses UV curable polymer resin and is cured by ultraviolet rays.

7. The method as claimed in claim 4, wherein only resist on the bright region of the mask is cured.

8. The method as claimed in claim 1, wherein the micro pattern includes a nano-level grid pattern for a wire grid polarizer, and a nano-level or micro-level functional pattern having a concave-convex section such as a reflective pattern having a three dimensional shape.

9. The method as claimed in claimed 1, wherein the plurality of small molds has different patterns each other.

10. The method as claimed in claimed 1, wherein the mask has a substrate structure in which on a surface of the mask is formed with a predetermined pattern using an emulsion or a metal layer.

11. A method for forming a large-sized micro pattern using a mask mold, the method comprising:
preparing a mask mold by forming micro patterns, which are engraved on a plurality of small molds, on one mask; and
forming the micro patterns of the mask mold on a large-sized substrate.

12. The method as claimed in claim 11, wherein the large-sized micro pattern is formed through operations:
coating resist on the large-sized substrate or the mask mold;
aligning the large-sized substrate and the mask mold;
pressing the mask mold to imprint the micro patterns on the resist;
curing the resist;
releasing the mask mold from the resist; and
cleaning residual uncured resist.

13. The method as claimed in claim 12, further comprising forming the micro patterns on a whole area of the large-sized substrate by repeating the operations.

14. The method as claimed in claim 12, wherein the resist uses UV curable polymer resin and is cured by ultraviolet rays.

15. The method as claimed in claim 12, wherein the resist, which is used for manufacturing the mask mold, includes a material different from a material of the resist used for forming the large-sized micro pattern.

16. The method as claimed in claim 12, further comprising performing release coating on the resist of the mask mold if two resists use the same material.

17. The method as claimed in claim 12, wherein, aligning the large-sized substrate and the mask mold, the large-sized substrate and the mask mold are aligned in such a manner that an align mark formed on the mask mold matches with an align mark formed on the large-sized substrate, and then are aligned in such a manner that a boundary of the micro patterns previously formed on the large-sized substrate matches with a boundary of micro patterns of the mask mold to be additionally formed.

18. The method as claimed in claim 12, wherein, curing the resist, only resist between a bright region of the mask mold and the large-sized substrate is cured.

19. A mask mold comprising:
a mask: and
resist locally forming a micro pattern on the mask.

20. The mask mold as claimed in claim 19, wherein the mask includes patterns formed on bright and dark regions.

21. The mask mold as claimed in claim 18, wherein the micro pattern is formed on only the bright region of the mask.

22. The mask mold as claimed in claim 19, wherein the micro pattern includes a nano-level grid pattern for a wire grid polarizer, and a nano-level or micro-level functional pattern having a concave-convex section such as a reflective pattern having a three dimensional shape.

23. A process for forming a micro-pattern, comprising:
forming a micro-pattern on a set of adjacently positioned molds with each mold having a size smaller than a substrate;
coating the molds with a resist; and
pressing the molds against the substrate until the resist is cured.

24. A process for forming a micro-pattern as claimed in claim 23, further comprising repeating the coating and pressing at a different location on the substrate.

25. A kit for micro-pattern molding, comprising:
a set of adjacently positioned molds each having a mold pattern offset from each other; and
a mask having mask regions correlated to the molds.
